(19) United States
(12) Patent Application Publication
(10) Pub. No.: US 2020/0168563 A1
(43) Pub. Date: May 28, 2020

(54) ELECTRONIC DEVICE AND METHOD OF MANUFACTURING ELECTRONIC DEVICE

(71) Applicant: FUJITSU LIMITED, Kawasaki-shi (JP)

(72) Inventors: Masaru Morita, Isehara (JP); Yoshihiro Nakata, Atsugi (JP)

(73) Assignee: FUJITSU LIMITED, Kawasaki-shi, Kanagawa (JP)

(21) Appl. No.: 16/590,691

(22) Filed: Oct. 2, 2019

(30) Foreign Application Priority Data
Nov. 22, 2018 (JP) 2018-219765

(51) Int. Cl. H01L 23/00; H01L 23/498; H01L 21/48

(52) U.S. Cl. CPC H01L 23/562; H01L 21/4846; H01L 23/49866; H01L 23/49838

(57) ABSTRACT

An electronic device includes a substrate and a wiring. The wiring is provided above the substrate and includes a Ni—B layer and a copper layer provided on the Ni—B layer. The Ni—B layer contains 3.2% by weight to 5% by weight of boron.

### CROSS-REFERENCE TO RELATED APPLICATION

This application is based upon and claims the benefit of priority of the prior Japanese Patent Application No. 2018-219765, filed on Nov. 22, 2018, the entire contents of which are incorporated herein by reference.

### FIELD

The embodiment discussed herein is related to an electronic device and a method of manufacturing the electronic device.

### BACKGROUND

An electronic device such as a server, a high-performance computing (HPC) device, a gaming device, or a graphics processing unit (GPU) includes a plurality of semiconductor devices such as a processor and a memory. The plurality of semiconductor devices are coupled to one another by wiring. Miniaturization of terminals formed in a semiconductor device has progressed in accordance with progress of semiconductor process technology, and thus the width of each wire formed in the electronic device has decreased.

As a technique of forming wiring, a method (semi-additive process) of forming a seed layer including an adhesion layer and a power supply layer on a substrate by a sputtering process, forming a mask including an opening portion on the seed layer by exposure and development of a photoresist, and forming a conductive layer by electroplating using the seed layer exposed through the opening portion as an electrode is known (for example, see Japanese Laid-open Patent Publication No. 2012-69718).

When the formed wiring is left to stand at a normal temperature, the formed wiring regrows such that crystal grains therein move and are bonded to each other, and thus have larger crystal grains and fewer crystal grain boundaries than immediately after being formed. Since the crystal grain boundaries are likely to be affected by corrosion, fewer crystal grain boundaries lead to higher corrosion resistance of the wiring.

When the width of each wire of an electronic device is smaller than 100 nm, the volume of metal of the wiring is small, therefore it is difficult for the crystal grains in the wiring to move and it is difficult for the regrowth to progress. The wiring in a state in which the regrowth does not progress much and many crystal grain boundaries are present has low corrosion resistance and causes malfunction of the electronic device.

In one aspect, an object of the embodiment is to provide a highly reliable electronic device.

### SUMMARY

According to an aspect of the embodiments, an electronic device includes: a substrate; and wiring provided above the substrate and including a Ni—B layer and a copper layer provided on the Ni—B layer, the Ni—B layer containing 3.2% by weight to 5% by weight of boron.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1A is a diagram for describing a step of preparing a substrate in a method of manufacturing a wiring board according to an embodiment;

FIG. 1B is a diagram for describing a step of forming an adhesion layer on the substrate in the method of manufacturing the wiring board according to the embodiment;

FIG. 1C is a diagram for describing a step of forming a power supply layer on the adhesion layer in the method of manufacturing the wiring board according to the embodiment;

FIG. 1D is a diagram for describing a step of forming a wiring growing layer on the power supply layer in the method of manufacturing the wiring board according to the embodiment;

FIG. 1E is a diagram for describing a step of forming a resist pattern in the method of manufacturing the wiring board according to the embodiment;

FIG. 1F is a diagram for describing a step of forming conductive layers in the method of manufacturing the wiring board according to the embodiment;

FIG. 1G is a diagram for describing a step of removing the resist pattern in the method of manufacturing the wiring board according to the embodiment;

FIG. 1H is a diagram for describing a step of etching a seed layer (wiring growing layer, power supply layer, and adhesion layer) in the method of manufacturing the wiring board according to the embodiment;

FIG. 1I is a diagram for describing a step of performing activator treatment on wiring in the method of manufacturing the wiring board according to the embodiment;

FIG. 13 is a diagram for describing a step of forming cap layers on the wiring in the method of manufacturing the wiring board according to the embodiment;

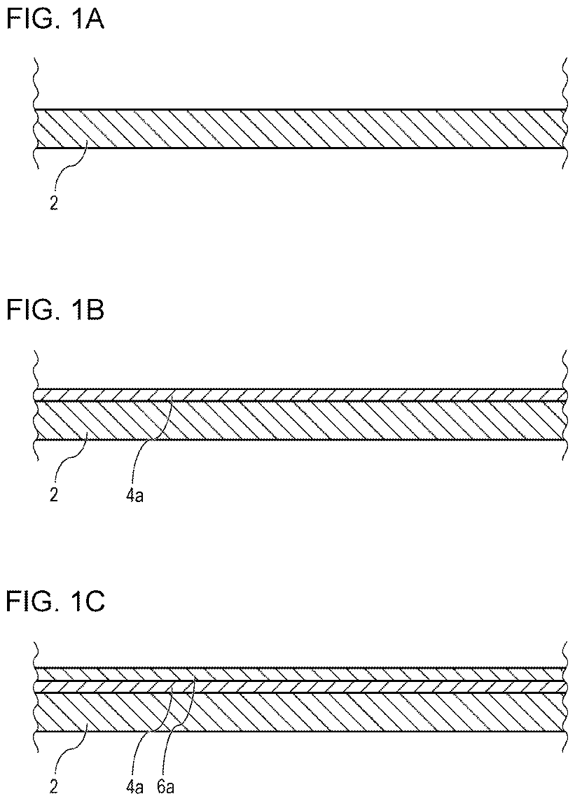

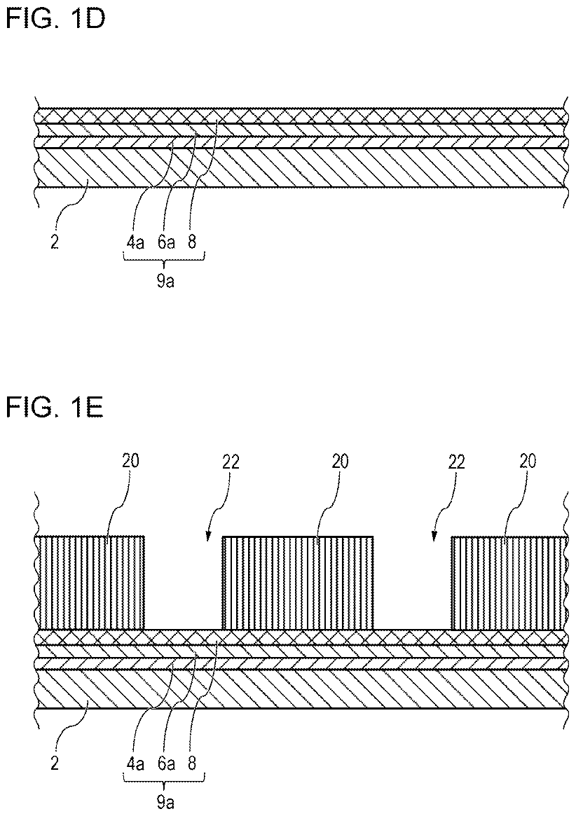

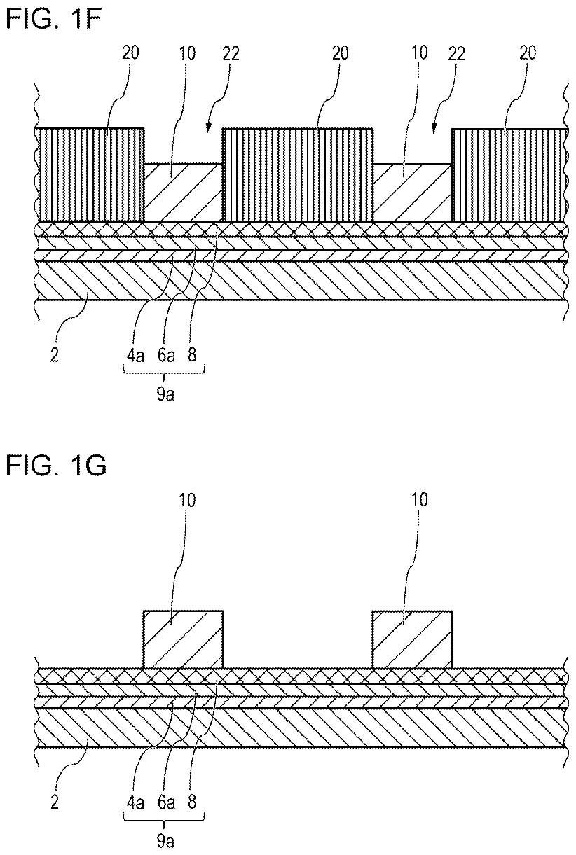

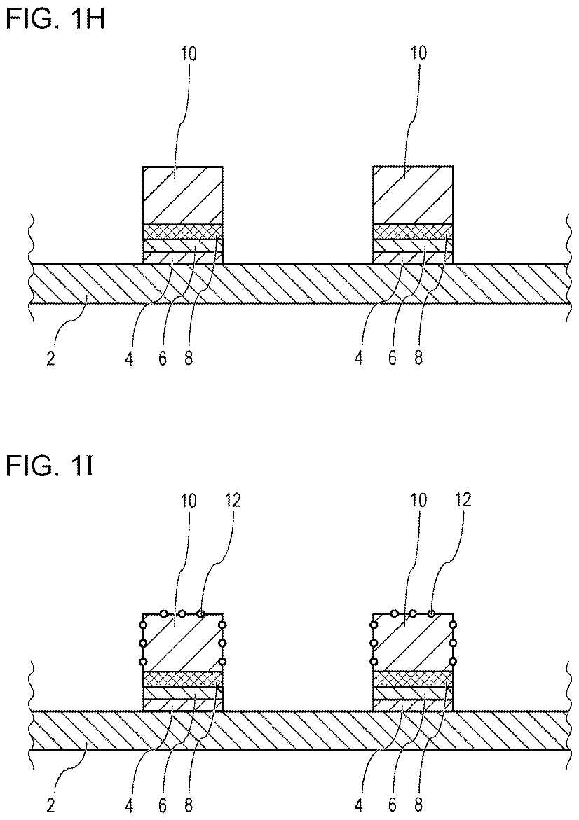

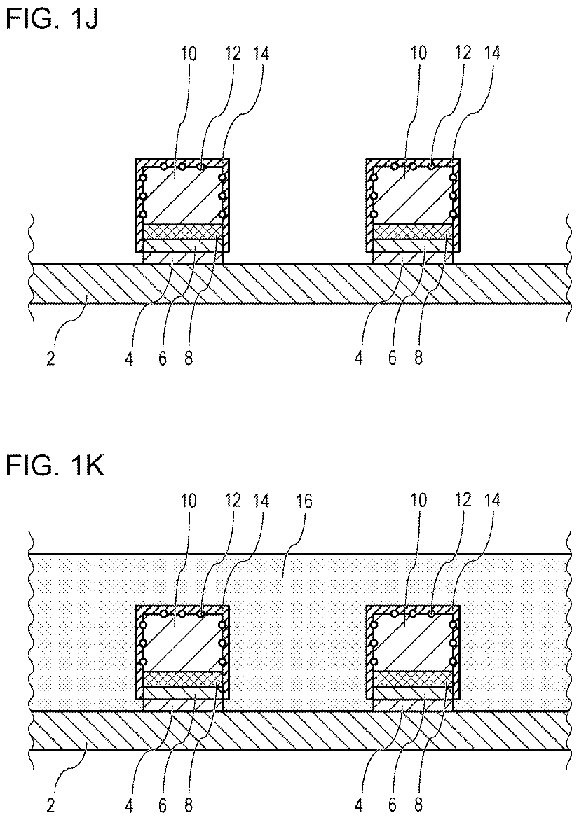

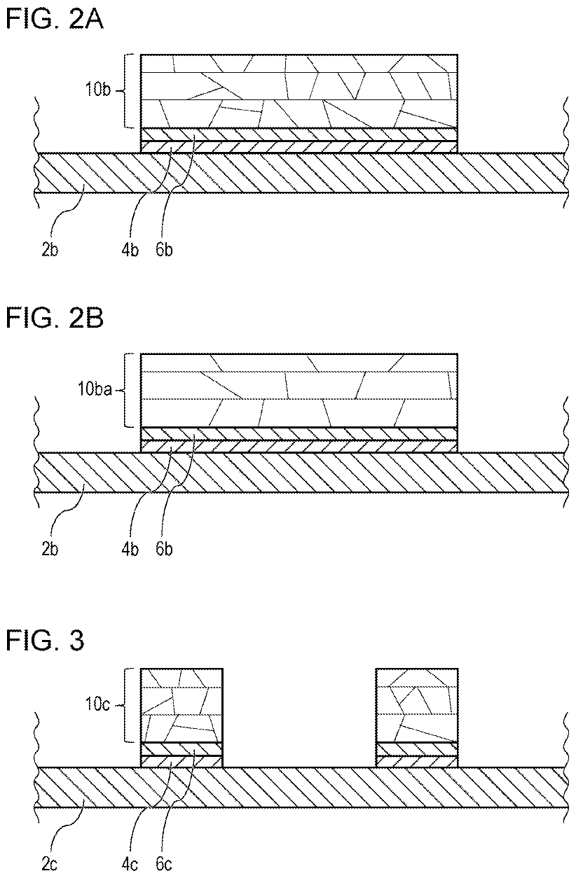

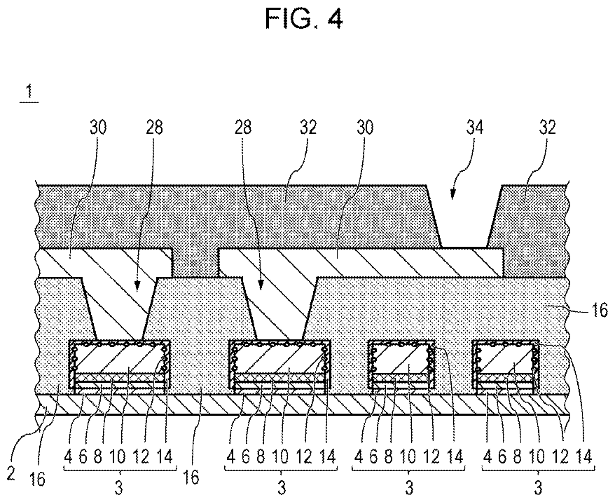

FIG. 1K is a diagram for describing a step of forming an insulating layer covering the wiring in the method of manufacturing the wiring board according to the embodiment;

FIG. 2A is a diagram illustrating metal crystal grains in a conductive layer immediately after a step of forming the conductive layer in a method of manufacturing a wiring board according to a comparative example;

FIG. 2B is a diagram illustrating metal crystal grains in the conductive layer after regrowth of the metal crystal grains in the conductive layer in the method of manufacturing the wiring board according to the comparative example;

FIG. 3 is a diagram illustrating metal crystal grains in a conductive layer in a method of manufacturing a wiring board according to another comparative example; and

FIG. 4 is a diagram illustrating the wiring board according to the embodiment.

### DESCRIPTION OF EMBODIMENTS

A wiring board and a method of manufacturing the wiring board will be described below as an electronic device and a method of manufacturing the electronic device according to an embodiment with reference to drawings. The technical scope is not limited to the embodiment, and includes what is described in the claims and equivalents thereof. Corresponding elements in different drawings are denoted by the same reference signs, and the description thereof is omitted.

A method of manufacturing a wiring board will be described below as a method of manufacturing a wiring board according to the embodiment with reference to FIGS. 1A to 1K. The method of manufacturing the wiring board according to the embodiment includes forming wiring including a Ni—B layer and a copper layer above a substrate, the Ni—B layer containing 3.2% by weight to 5% by weight of boron.

In the method of manufacturing the wiring board according to the embodiment, wiring formation by a semi-additive process is performed.

A substrate 2 is prepared as illustrated in FIG. 1A. The substrate 2 is a semiconductor substrate or a wiring board on which an integrated circuit is formed. The substrate 2 is, for example, a silicon wafer or a resin substrate.

Next, metal is deposited on the substrate 2 by sputtering, and thus an adhesion layer 4a is formed as illustrated in FIG. 1B. The adhesion layer 4a is formed from, for example, titanium or chromium. The film thickness of the adhesion layer 4a is, for example, 0.01 μm to 0.1 μm.

Next, metal is deposited on the adhesion layer 4a by sputtering, and thus a power supply layer 6a is formed as illustrated in FIG. 1C. The formation of the power supply layer 6a may be performed by, for example, electroless plating. The film thickness of the power supply layer 6a is preferably 0.03 μm or more from the viewpoint of reducing the resistance of the power supply layer 6a in an electroless plating step in formation of conductive layers that will be described later to improve the yield of the conductive layers. The power supply layer 6a is formed from, for example, copper, nickel, or Ni—Cr.

Next, electroless plating of Ni-B is performed on the power supply layer 6a, and a wiring growing layer 8a is formed as illustrated in FIG. 1D. The film thickness of the wiring growing layer 8a is preferably 0.03 μm or more from the viewpoint of supplying sufficient power in the electroless plating step of the formation of the conductive layers that will be described later to suppress occurrence of plating failure such as plating burn and improve the yield. The electroless plating is performed by, for example, immersing the substrate in a heated plating bath.

Three layers including the adhesion layer 4a, the power supply layer 6a, and the wiring growing layer 8a that have been formed are collectively referred to as a seed layer 9a. The seed layer 9a is used as an electrode in an electroplating step of the formation of conductive layers that will be described later. The film thickness of the wiring growing layer 8a is preferably 0.1 μm or less from the viewpoint of suppressing peeling of the conductive layers caused by side etching in a step of etching the seed layer 9a that will be described later and improve the reliability.

The plating rate of the wiring growing layer 8a is, for example, about 0.05 μm per 30 seconds. The plating formation time of the wiring growing layer 8a is preferably 15 seconds or more from the viewpoint of stabilizing adjustment of the film thickness.

Next, a photoresist is applied on the wiring growing layer 8a, is exposed and developed at a desired position, and is thus patterned into a desired shape, and thus a resist 20 including opening portions 22 is formed as illustrated in FIG. 1E. The opening portions 22 of the resist 20 are provided at regions where conductive layers 10 are to be formed. The seed layer 9a covered by the resist 20 is partially exposed through the opening portions 22.

Next, metal plating is grown on the wiring growing layer 8a by electroplating using the seed layer 9a exposed right under the opening portions 22 of the resist 20 as an electrode, and thus the conductive layers 10 are formed in the opening portions 22 of the resist 20 as illustrated in FIG. 1F. In the electroplating for forming the conductive layers 10, for example, an electroplating copper solution is used, the current density is set to 8 A/dm², and the plating temperature is set to 30° C.

Next, the resist 20 is removed, and the conductive layers 10 remain on the wiring growing layer 8a as illustrated in FIG. 1G.

Next, the seed layer 9a is partially removed by wet-etching a portion of the seed layer 9a not covered by the conductive layers 10. As a result of this, the plurality of electrically independent conductive layers 10 remain on the substrate 2 as illustrated in FIG. 1H. In the removal of the seed layer 9a, for example, in the case where the seed layer 9a includes the adhesion layer 4a of titanium and the power supply layer 6a of copper, the power supply layer 6a of copper is removed by using a mixture liquid of acetic acid, aqueous solution of hydrogen peroxide, and water, and then the adhesion layer 4a of titanium is removed by using a mixture liquid of hydrofluoric acid and water.

Next, the substrate 2 on which the conductive layers 10 have been formed is immersed in a bath of an activator liquid containing catalyst metal, and thus a catalyst 12 is attached to the surface of the conductive layers 10 as illustrated in FIG. 1I. The catalyst 12 is, for example, palladium or silver.

Next, electroless plating is performed on the surface of the conductive layers 10, and thus cap layers 14 are formed as illustrated in FIG. 1. The cap layers 14 are formed from, for example, Ni-P, Ni-B, Ni-Co, tin, Co-W, or Co-B.

Next, an insulating resin is applied and heated to cure on the conductive layers 10, and thus an insulating layer 16 covering the conductive layers 10 is formed as illustrated in FIG. 1K. The material of the insulating layer 16 is, for example, polyimide.

The method of forming the wiring is not limited to a semi-additive process, and may be, for example, a damascene process.

The wiring board manufactured by the manufacturing method described above may have higher corrosion resistance of wiring, less deterioration over time, and higher reliability.

A wiring growing layer 8 of Ni-B containing 3.2% by weight to 5% by weight of boron is amorphous and does not include fine crystals. On the amorphous wiring growing layer 8, copper crystal grains included in the conductive layers 10 regrow and the crystal grain size thereof becomes 1 μm or more. This is because the size of the crystal grains of metal plating formed by the electroplating depends on the size of metal crystal grains of a layer thereunder. The amorphous wiring growing layer 8 does not include fine crystals, and copper crystal grains whose crystal grain size is smaller than 1 μm included in the conductive layers 10 are unstable. The copper crystal grains having a crystal grain size less than 1 μm are stabilized by regrowth. The copper crystal grains included in the regrown conductive layers 10 have a crystal grain size of 1 μm or more.

The conductive layers 10 including copper crystal grains having a crystal grain size of 1 μm or more may have fewer crystal grain boundaries and higher corrosion resistance. The conductive layers 10 including copper crystal grains having a crystal grain size of 1 μm or more may suppress generation of voids caused by activator treatment, and therefore the wiring may have lower electrical resistance.

A method of manufacturing a wiring board according to a first comparative example will be described with reference to FIGS. 2A and 2B. The method of manufacturing the wiring board according to the first comparative example is different from the method of manufacturing the wiring board according to the embodiment in that a conductive layer is directly formed on the power supply layer without forming the wiring growing layer.

As illustrated in FIG. 2A, an adhesion layer 4b is formed on a substrate 2b, a power supply layer 6b is formed on the adhesion layer 4b, and a conductive layer 10b is formed on the power supply layer 6b. The conductive layer 10b immediately after being formed includes copper crystal grains having a crystal grain size less than 1 μm, and does not include copper crystal grains having a crystal grain size of 1 μm or more. The conductive layer 10b has a thickness larger than 0.1 μm in a direction perpendicular to the substrate 2b.

When a certain time elapses at a normal temperature after the conductive layer 10b is formed, the copper crystal grains included in the conductive layer 10b move and are bonded to each other (regrow), and thus the copper crystal grains become larger than immediately after being formed. The certain time is, for example, 4 hours or more.

As illustrated in FIG. 2B, a conductive layer 10ba is formed on the power supply layer 6b. The conductive layer 10ba is the conductive layer 10b illustrated in FIG. 2A after the elapse of the certain time, and includes copper crystal grains having a crystal grain size of 1 μm or more. The conductive layer 10ba including copper crystal grains having a crystal grain size of 1 μm or more have fewer crystal grain boundaries and higher corrosion resistance.

A method of manufacturing a wiring board according to a second comparative example will be described with reference to FIG. 3. The method of manufacturing the wiring board according to the second comparative example is different from the method of manufacturing the wiring board according to the first comparative example in that the conductive layer is finer.

As illustrated in FIG. 3, adhesion layers 4c are formed on a substrate 2c, power supply layers 6c are formed on the adhesion layers 4c, and conductive layers 10c are formed on the power supply layers 6c. The conductive layers 10c immediately after being formed include copper crystal grains having a crystal grain size less than 1 μm, and do not include copper crystal grains having a crystal grain size of 1 μm or more. The conductive layers 10c have a thickness of 0.1 μm or less in a direction perpendicular to the substrate 2c.

The copper crystal grains included in the conductive layer 10c do not regrow even when a certain time elapses at a normal temperature after the conductive layers 10c are formed. The reason why the regrowth does not occur is because the volumes of the conductive layers 10c are smaller than the volume of the conductive layer 10b illustrated in FIG. 2A and the crystal grains do not move in the conductive layers 10c. The conductive layers 10c do not include copper crystal grains having a crystal grain size of 1 μm or more even after the elapse of the certain time. The conductive layers 10c that do not regrow and do not include copper crystal grains having a crystal grain size of 1 μm or more have more crystal grain boundaries and lower corrosion resistance. Many crystal grain boundaries, which are boundaries of crystal grains, intersect in the surface of the conductive layers 10c, and become starting points of corrosion.

When activator treatment is performed on a conductive layer 10 including copper crystal grains having a crystal grain size less than 1 μm, surface particles of the conductive layer 10 are replaced by the catalyst 12, and this causes generation of voids.

The wiring board according to the embodiment will be described with reference to FIG. 4. As illustrated in FIG. 4, a wiring board 1 includes the substrate 2, wires 3, an insulating layer 16, leader lines 30, and an insulating layer 32. Although the illustration is omitted herein, more wiring is formed on the insulating layer 32, and terminals to be coupled to a semiconductor device are formed.

The wires 3 are formed on the substrate 2, and include adhesion layers 4, power supply layers 6, wiring growing layers 8, conductive layers 10, the catalyst 12, and cap layers 14. A plurality of the wires 3 are formed and serve as wiring layers of the wiring board 1. The width of each of the plurality of wires 3 is, for example, 5 μm. Intervals between the plurality of wires 3 are, for example, 10 μm.

The adhesion layers 4 are formed on the substrate 2. The adhesion layers 4 enhance adhesion between the substrate 2 and layers to be formed on the adhesion layers 4. The film thickness of the adhesion layers 4 is, for example, 0.01 μm to 0.1 μm. The adhesion layers 4 are, for example, metal films of titanium, chromium, or the like.

The power supply layers 6 are formed on the adhesion layers 4. The film thickness of the power supply layers 6 is, for example, 0.03 μm to 0.1 μm. The power supply layers 6 are, for example, metal films of copper, nickel, Ni—Cr, or the like.

The wiring growing layers 8 are formed on the power supply layers 6. The film thickness of the wiring growing layers 8 is preferably 0.04 μm to 0.3 μm from the viewpoint of small film stress and improvement of the reliability of the wiring board 1. The wiring growing layers 8 are Ni-B films containing 3.2% by weight to 5% by weight of boron.

The conductive layers 10 are formed on the wiring growing layers 8. The conductive layers 10 serve as conductive paths of the wiring board 1. The film thickness of the conductive layers 10 is, for example, 15 μm.

The catalyst 12 is formed on the surface of the conductive layers 10. The catalyst 12 is, for example, palladium or silver.

The cap layers 14 are formed on the conductive layers 10, the wiring growing layers 8, and the power supply layers 6. The cap layers 14 suppress heat dissipation from the wires 3 to the insulating layer 16. The cap layers 14 are formed from, for example, Ni-P, Ni-B, Ni-Co, tin, Co-W, or Co-B.

The insulating layer 16 covers the plurality of wires 3. The insulating layer 16 includes opening portions 28. The insulating layer 16 is formed from, for example, polyimide.

The leader lines 30 are coupled to the wires 3 through the opening portions 28.

The insulating layer 32 covers the leader lines 30. The insulating layer 32 includes an opening portion 34. The opening portion 34 is provided for securing conduction between the leader lines 30 and a conduction portion provided above the insulating layer 32 to couple the conduction portion provided above the insulating layer 32 to the wires 3.

In the wiring board 1 described above, the wires 3 may have higher corrosion resistance, less deterioration over time, and high reliability.

Wiring boards according to Examples 1 to 5 will be described below.

The wiring boards according to Examples 1 to 5 included the wires 3 (the adhesion layers 4, the power supply layers 6, the wiring growing layers 8, the conductive layers 10, and the cap layers 14) illustrated in FIG. 4.

### Example 1

The adhesion layers 4 were formed from titanium by sputtering on the substrate 2 of a silicon wafer. The film thickness of the adhesion layers 4 was 0.03 μm.

The power supply layers 6 were formed from nickel by sputtering on the adhesion layers 4. The film thickness of the power supply layers 6 was 0.03 μm.

The wiring growing layers 8 were formed from Ni-B by electroless plating on the power supply layers 6, and contained 5.0% by weight of boron. The film thickness of the wiring growing layers 8 was 0.05 μm. The electroless plating of the wiring growing layers 8 was performed by removing oxide films of the power supply layers 6 of nickel with dilute sulfuric acid and immersing the substrate 2 of silicon wafer on which the adhesion layers 4 and the power supply layers 6 had been formed in a plating bath heated to about 6° C. for about 40 seconds.

The conductive layers 10 were formed from copper by electroplating on the wiring growing layers 8. The film thickness of the conductive layers 10 was 1 μm. The width of the conductive layers 10 in a direction perpendicular to the substrate 2 was 0.7 μm.

The cap layers 14 were formed from Ni-P by attaching the catalyst 12 of palladium to the surface of the conductive layers 10 and performing electroless plating. The film thickness of the cap layers 14 was 0.05 μm.

### Example 2

The wiring growing layers 8 were formed from Ni-B by electroless plating on the power supply layers 6, and contained 3.2% by weight of boron. The film thickness of the wiring growing layers 8 was 0.04 μm.

The other elements were the same as in Example 1.

### Example 3

The adhesion layers 4 were formed from titanium by sputtering on the substrate 2 of a silicon wafer. The film thickness of the adhesion layers 4 was 0.03 μm.

The power supply layers 6 were formed from copper by sputtering on the adhesion layers 4. The film thickness of the power supply layers 6 was 0.05 μm.

The wiring growing layers 8 were formed from Ni-B by electroless plating on the power supply layers 6, and contained 3.8% by weight of boron. The film thickness of the wiring growing layers 8 was 0.04 μm.

The conductive layers 10 were formed from copper by electroplating on the wiring growing layers 8. The film thickness of the conductive layers 10 was 1 μm. The width of the conductive layers 10 in a direction perpendicular to the substrate 2 was 1 μm.

The cap layers 14 were formed from Ni-B-P by attaching the catalyst 12 of palladium to the surface of the conductive layers 10 and performing electroless plating. The film thickness of the cap layers 14 was 0.05 μm.

### Example 4

The wiring growing layers 8 were formed from Ni-B by electroless plating on the power supply layers 6, and contained 3.8% by weight of boron. The film thickness of the wiring growing layers 8 was 0.2 μm.

The other elements were the same as in Example 3.

### Example 5

The wiring growing layers 8 were formed from Ni-B by electroless plating on the power supply layers 6, and contained 3.8% by weight of boron. The film thickness of the wiring growing layers 8 was 0.3 μm.

The other elements were the same as in Example 3.

In Examples 1 to 5, the crystal grain size of copper of the conductive layers 10 became 1 μm or more. The conductive layers 10 including copper crystal grains of 1 μm or more may have fewer crystal grain boundaries and higher corrosion resistance. No interlayer adhesion failure was observed in the wires 3.

Wiring boards according to Comparative Examples 1 to 7 will be described below.

The wiring boards according to Comparative Examples 1 to 7 included the wires 3 (the adhesion layers 4, the power supply layers 6, the wiring growing layers 8, the conductive layers 10, and the cap layers 14) illustrated in FIG. 4.

### Comparative Example 1

The wiring growing layers 8 were formed from Ni-B by electroless plating on the power supply layers 6, and contained 3.8% by weight of boron. The film thickness of the wiring growing layers 8 was 0.5 μm.

The other elements were the same as in Example 3.

As in Comparative Example 1, the wiring growing layers 8 having a boron content of 3.8% in a nickel film is cracked by the stress of the wiring growing layers 8 themselves in the case where the film thickness is 0.5 μm or more.

### Comparative Example 2

The wiring growing layers 8 were formed from nickel by electroless plating on the power supply layers 6. The film thickness of the wiring growing layers 8 was 0.05 μm.

The other elements were the same as in Example 3.

### Comparative Example 3

The wiring growing layers 8 were formed from Ni-B by electroless plating on the power supply layers 6, and contained 0.3% by weight of boron. The film thickness of the wiring growing layers 8 was 0.05 μm.

The other elements were the same as in Example 3.

As in Comparative Examples 2 and 3, a thick oxide film is formed on the wiring growing layers 8 having a boron content of 0.3% or less in a nickel film when the wiring growing layers 8 are formed, and thus plating failure occurs when plating the conductive layers 10.

### Comparative Example 4

The wiring growing layers 8 were formed from Ni-B by electroless plating on the power supply layers 6, and contained 0.5% by weight of boron. The film thickness of the wiring growing layers 8 was 3.0 μm.

The other elements were the same as in Example 3.

### Comparative Example 5

The wiring growing layers 8 were formed from Ni-B by electroless plating on the power supply layers 6, and contained 1.0% by weight of boron. The film thickness of the wiring growing layers 8 was 3.0 μm.

### Comparative Example 6

The wiring growing layers 8 were formed from Ni-B by electroless plating on the power supply layers 6, and contained 1.6% by weight of boron. The film thickness of the wiring growing layers 8 was 3.0 μm.

The other elements were the same as in Example 3.

In Comparative Examples 4 to 6, the wiring growing layers 8 having a boron content of 0.5% to 1.6% in a nickel film had high oxidation resistance as a result of containing boron, thus plating failure of the conductive layers 10 did not occur, but the effect of the copper crystal grains of the conductive layers 10 becoming larger was not obtained.

### Comparative Example 7

The wiring growing layers 8 were formed from Ni-B by electroless plating on the power supply layers 6, and contained 6.0% by weight of boron. The film thickness of the wiring growing layers 8 was 0.05 μm.

The other elements were the same as in Example 1.

As in Comparative Example 7, the wiring growing layers 8 having a boron content of 6.0% in a nickel film is cracked by the stress of the wiring growing layers 8 themselves. This is because more of a gas generated when forming the wiring growing layers 8 is contained in the wiring growing layers 8 and increases the stress more when the boron content in a nickel film of the wiring growing layers 8 is higher.

The following table includes the boron content and film thickness of the wiring growing layers 8, the yield of the wires 3, and the crystal grain size of copper included in the conductive layers 10 of Examples 1 to 5 and Comparative Examples 1 to 7.

TABLE 1

| | Boron | | | |
|---|---|---|---|---|
| | content | Film | | |
| | of wiring | thickness | | |
| | growing | of wiring | | |
| | layers | growing | | Crystal |
| | (% by | layers | Yield of | grain size |
| | weight) | (μm) | wires | of copper |
| Example 1 | 5.0 | 0.05 | Film is able to | Increases |
| | | | be formed | to 1 μm or |
| | | | | more |
| Example 2 | 3.2 | 0.05 | Film is able to | Increases |
| | | | be formed | to 1 μm or |
| | | | | more |
| Example 3 | 3.8 | 0.04 | Film is able to | Increases |
| | | | be formed | to 1 μm or |
| | | | | more |
| Example 4 | 3.8 | 0.2 | Film is able to | Increases |
| | | | be formed | to 1 μm or |
| | | | | more |
| Example 5 | 3.8 | 0.3 | Film is able to | Increases |
| | | | be formed | to 1 μm or |
| | | | | more |
| Comparative | 3.8 | 0.5 | Wiring growing | — |
| Example 1 | | | layers are | |
| | | | cracked by film | |
| | | | stress | |
| Comparative | 0 | 0.05 | Plating failure of | — |
| Example 2 | | | conductive | |
| | | | layers occurs | |
| Comparative | 0.3 | 0.05 | Plating failure of | — |
| Example 3 | | | conductive | |
| | | | layers occurs | |
| Comparative | 0.5 | 3 | Film is able to | No increase |
| Example 4 | | | be formed | is observed |
| Comparative | 1 | 3 | Film is able to | No increase |
| Example 5 | | | be formed | is observed |
| Comparative | 1.6 | 3 | Film is able to | No increase |
| Example 6 | | | be formed | is observed |
| Comparative | 6.0 | 0.05 | Wiring growing | — |
| Example 7 | | | layers are | |
| | | | cracked by film | |
| | | | stress | |

A value of electrical resistance after a reliability test was compared between the wires 3 of the wiring board of Example 1 and wires of a wiring board of Comparative Example 8 that will be described later.

### Comparative Example 8

The wiring board according to Comparative Example 8 included wires (adhesion layers, power supply layers, conductive layers, and cap layers 14).

The adhesion layers were formed from titanium by sputtering on a substrate of a silicon wafer. The film thickness of the adhesion layers was 0.03 μm.

The power supply layers were formed from copper by sputtering on the adhesion layers. The film thickness of the power supply layers was 0.05 μm.

The conductive layers were formed from copper by electroplating on the power supply layers. The film thickness of the conductive layers was 1 μm. The width of the conductive layers in a direction perpendicular to the substrate was 0.7 μm.

The cap layers were formed from Ni-P by attaching a catalyst of palladium to the surface of the conductive layers and performing electroless plating. The film thickness of the cap layers was 0.05 μm.

Values of electrical resistance of the wires 3 of the wiring board of Example 1 and the wires of the wiring board of Comparative Example 8 after the reliability test were measured by using a prober.

As the reliability test, a high-temperature acceleration test was conducted after performing moisture absorption reflow on a sample of wiring board. In the moisture absorption reflow, peak reflow was conducted three times in conditions of 125° C. for 24 hours, 60° C. and 60% RH, and 260° C. In the high-temperature acceleration test, the sample of wiring board was left to stand in a thermostat chamber of 200° C. for 24 hours.

Increase rate of the value of electrical resistance after the reliability test with respect to the value of electrical resistance before the reliability test was 5.9% for the wires 3 of the wiring board of Example 1 and 11.2% for the wires of the wiring board of Comparative Example 8.

When the increase rate of the value of electrical resistance after the reliability test is lower, the influence of deterioration over time is suppressed more, and the reliability is higher.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An electronic device comprising:
a substrate; and
wiring provided above the substrate and including a Ni—B layer and a copper layer provided on the Ni—B layer, the Ni—B layer containing 3.2% by weight to 5% by weight of boron.

2. The electronic device according to claim 1, wherein the Ni—B layer is amorphous.

3. The electronic device according to claim 1, wherein the copper layer includes copper crystal grains of 1 μm or more.

4. The electronic device according to claim 1, wherein the copper layer has a thickness of 100 nm or less in a direction perpendicular to the substrate.

5. The electronic device according to claim 1, further comprising a cap layer formed from metal and covering the copper layer.

6. The electronic device according to claim 5, wherein the cap layer is an electroless plating film containing one of nickel, tin, and cobalt.

7. The electronic device according to claim 6, further comprising a catalyst of palladium or silver between the copper layer and the cap layer.

8. The electronic device according to claim 1, further comprising a power supply layer provided between the substrate and the Ni—B layer and containing one of copper, nickel, and Ni—Cr.

9. The electronic device according to claim 1, further comprising an adhesion layer provided between the substrate and the Ni—B layer and containing one of titanium and chromium.

10. The electronic device according to claim 1, wherein the Ni—B layer has a thickness of 40 nm to 300 nm in a direction perpendicular to the substrate.

11. A method of manufacturing an electronic device, the method comprising;
providing a substrate; and
forming, above the substrate, wiring including a Ni—B layer and a copper layer on the Ni—B layer, wherein the Ni—B layer containing 3.2% by weight to 5% by weight of boron.

12. The method of manufacturing an electronic device according to claim 11, the method further comprising:
forming a catalyst of palladium or silver around the copper layer by performing activator treatment on the copper layer; and
forming, by electroless plating, a cap layer covering the copper layer and containing one of nickel, tin, and cobalt.
